(19) United States
(12) Patent Application Publication
(10) Pub. No.: US 2025/0174436 A1
(43) Pub. Date: May 29, 2025

(54) Source Tuning With Pulsed DC Bias

(71) Applicant: MKS Instruments, Inc., Andover, MA (US)

(72) Inventors: Aaron RADOMSKI, Conesus, NY (US); Aaron BURRY, Ontario, NY (US); Mariusz OLDZIEJ, Avon, NY (US)

(21) Appl. No.: 18/523,178

(22) Filed: Nov. 29, 2023

(51) Int. Cl. H01J 37/32

(52) U.S. Cl. CPC H01J 37/32183; H01J 2237/327

(57) ABSTRACT

A RF generator includes a RF power source. The RF power source outputs a time-varying signal to a load. At least one controller is coupled to the RF power source. The at least one controller is configured to generate an impedance control signal to control an impedance between the RF power source and the load. The at least one controller is further configured to generate the impedance control signal in response to a pulsed DC output signal from a second power source.

### FIELD

The present disclosure relates to RF generator systems and to control of RF generators.

### BACKGROUND

Plasma processing is frequently used in semiconductor fabrication. In plasma processing, ions are accelerated by an electric field to etch material from or deposit material onto a surface of a substrate. In one basic implementation, the electric field is generated based on Radio Frequency (RF) or Direct Current (DC) power signals generated by a respective RF or DC generator of a power delivery system. The power signals generated by the generator must be precisely controlled to effectively execute plasma etching.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One general aspect includes a RF generator having a power source that outputs a time-varying signal to a load. The generator also includes at least one controller coupled to the power source, the at least one controller configured to generate an impedance control signal to control an impedance between the power source and the load. is. The at least one controller is further configured to generate the impedance control signal in response to a pulsed DC output signal from a second power source. Other embodiments of this aspect include corresponding computer systems, apparatus, and computer programs recorded on one or more computer storage devices, each configured to perform the actions of the methods.

Implementations may include one or more of the following features. The RF generator where pulsed DC output signal has a plurality of half cycles, and the impedance control signal varies in accordance with at least one of the plurality of half cycles. The impedance control signal varies at least one of a frequency of the time-varying signal or an actuator command to a matching network. The actuator command varies elements of a matching network, including at least one reactive element. The pulsed DC output signal includes a plurality of half cycles, including a negative half cycle and a positive half cycle, and the impedance control signal controls the impedance over the negative half cycle. The negative half cycle has a duration longer than the positive half cycle. The pulsed DC output signal includes a plurality of half cycles, including a negative half cycle and a positive half cycle, and where the impedance control signal commands a first frequency of the time-varying signal during at least a portion of the negative half cycle. The impedance control signal commands a second frequency of the time-varying signal during at least a portion of the positive half cycle. The negative half cycle has a duration longer than the positive half cycle. The pulsed DC output signal is modulated by an envelope signal including a plurality of states, and where the at least one controller includes a first impedance tuner configured to determine the impedance control signal for a first of the plurality of states and the at least one controller includes a second impedance tuner configured to determine the impedance control signal for a second of the plurality of states. Implementations of the described techniques may include hardware, a method or process, or computer software on a computer-accessible medium.

One general aspect includes a controller for a power generator. The controller includes an impedance tuner coupled to a power source that outputs a time-varying signal to a load. The impedance tuner is configured to generate an impedance control signal to control an impedance match between the power source and the load. The impedance tuner is further configured to generate the impedance control signal in response to a pulsed DC output signal from a second power source. Other embodiments of this aspect include corresponding computer systems, apparatus, and computer programs recorded on one or more computer storage devices, each configured to perform the actions of the methods.

Implementations may include one or more of the following features. The controller where the pulsed DC output signal has a plurality of half cycles, and the impedance control signal varies in accordance with at least one of the plurality of half cycles. The impedance control signal varies at least one of a frequency of the time-varying signal or an actuator command to a matching network. The actuator command varies elements of a matching network, including at least one reactive element. The pulsed DC output signal has a plurality of half cycles, including a negative half cycle and a positive half cycle, and where the impedance control signal controls the impedance match over the negative half cycle and does not control the impedance match over the positive half cycle. The negative half cycle has a duration longer than the positive half cycle. The pulsed DC output signal has a plurality of half cycles, including a negative half cycle and a positive half cycle, and where the impedance control signal commands a first frequency of the time-varying signal during at least a portion of the negative half cycle. The impedance control signal commands a second frequency of the time-varying signal during at least a portion of the positive half cycle. The negative half cycle has a duration longer than the positive half cycle. The pulsed DC output signal has a plurality of half cycles, and where the impedance tuner includes a first tuner configured to determine the impedance control signal for a first of the plurality of half cycles and the impedance tuner includes a second tuner configured to determine the impedance control signal for a second of the plurality of half cycles. The impedance control signal varies a frequency of the time-varying signal using frequency hopping over a plurality of bins over at least a portion of the pulsed DC output signal. Implementations of the described techniques may include hardware, a method or process, or computer software on a computer-accessible medium.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a non-transitory computer-readable medium storing instructions. The non-transitory computer-readable medium storing instructions to control an impedance tuner coupled to a power source that outputs a RF signal to a load. The instructions also include generating an impedance control signal to control an impedance match between the power source and the load. The instructions also include generating the impedance control signal in response to a pulsed DC output signal from a second power source. Other embodiments of this aspect include corresponding computer systems, apparatus, and computer programs recorded on one or more computer storage devices, each configured to perform the actions of the methods.

Implementations may include one or more of the following features. The non-transitory computer-readable medium storing instructions where the pulsed DC output signal has a plurality of half cycles, and the instructions may include varying the impedance control signal in accordance with at least one of the plurality of half cycles or varying elements of a matching network including at least one reactive element. The pulsed DC output signal has a plurality of half cycles, including a negative half cycle and a positive half cycle, and the instructions may include controlling an impedance over the negative half cycle and not controlling the impedance in over the positive half cycle. The pulsed DC output signal has a plurality of half cycles, including a negative half cycle and a positive half cycle, and the instructions may include controlling a first frequency of the RF signal during at least a portion of the negative half cycle. The non-transitory computer-readable medium where the instructions may include controlling a second frequency of the RF signal during at least a portion of the positive half cycle. The pulsed DC output signal has a plurality of half cycles, and the instructions may include determining the impedance control signal for a first of the plurality of half cycles, and determining the impedance control signal for a second of the plurality of half cycles. Implementations of the described techniques may include hardware, a method or process, or computer software on a computer-accessible medium.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 shows a representation of an inductively coupled plasma processing system;

FIG. 2 shows a representation of a capacitively coupled plasma processing system;

FIG. 3 shows a generalized representation of a plasma system arranged according to various configurations of the present disclosure;

FIG. 4 shows an example plot of intermodulation distortion (IMD) resulting from applying two signals of different frequency to a non-linear reactor;

FIG. 5 shows a schematic block diagram of a power delivery system having multiple power supplies arranged according to various configurations of the present disclosure;

FIGS. 6A-B show waveforms of a time-varying signal and a pulse modulating the time-varying signal to describe a pulsed mode of operation;

FIGS. 6C-6F show various waveforms for DC carrier signals;

FIG. 7 shows a schematic block diagram of a portion of a power delivery system of FIG. 5 arranged according to various configurations of the present disclosure;

FIG. 8 shows a plot of sheath capacitance versus bias voltage;

FIG. 9 shows waveforms related to frequency tuning of a source generator during positive and negative half cycles of the bias generator output;

FIG. 10 shows waveforms related to frequency tuning the source generator during the negative half cycle of the bias generator output;

FIG. 11 shows waveforms related to frequency tuning the source generator during the negative half cycle of a bias generator output having a high negative half cycle duty cycle;

FIG. 12 shows waveforms related to frequency tuning a hopping pattern of the source generator with respect to the bias generator output;

FIG. 13 shows a plot of an example hopping pattern for frequency tuning associated with FIG. 12;

FIG. 14 shows a functional block diagram of an example control module arranged in accordance with various configurations; and

FIG. 15 shows a flow chart of operation of a control system arranged in accordance with the principals of the present disclosure.

In the drawings, reference numbers may be reused to identify similar and/or identical elements.

### DETAILED DESCRIPTION

A power system may include a DC or RF power generator or DC or RF generator, collectively referred to as generator or generators, a matching network, and a load (such as a process chamber, a plasma chamber, or a reactor having a fixed or variable impedance). The generator generates a DC power signal or a sinusoidal, RF, or other time-varying signal, which is received by the matching network or impedance optimizing controller or circuit. The matching network or impedance optimizing controller or circuit transforms a load impedance to a characteristic impedance of a transmission line between the generator and the matching network. Impedance matching aids in maximizing an amount of power delivered to the load (“delivered power”) and minimizing an amount of power reflected back from the load to the generator (“reverse power” or “reflected power”). Delivered power may be maximized by minimizing reflected power when the input impedance of the matching network matches the characteristic impedance of the transmission line and generator.

In the power source or power supply field, there are typically two approaches to applying a power signal to the load. A first, more traditional approach is to apply a continuous voltage, current, or power signal to the load. In a continuous mode or continuous wave mode, a continuous voltage, current, or power signal is typically a constant DC, sinusoidal, or periodic time-varying signal, which may be a RF or other voltage, current, or power signal, that is output continuously by the power source to the load. In the continuous mode approach, the voltage, current, or power signal assumes a constant DC or sinusoidal output, and the amplitude of the power signal and/or frequency (of a RF power signal) can be varied in order to vary the output power applied to the load.

A second approach to applying the power signal to the load involves pulsing a voltage, current, or power signal, rather than applying a continuous voltage, current, or power signal to the load. In a pulse or pulsed mode of operation, a voltage, current, or power signal or carrier signal is modulated by a modulation signal in order to define an envelope for the modulated power signal. The voltage, current, or power signal may be, for example, a sinusoidal RF signal or other periodic time-varying signal. Power delivered to the load is typically varied by varying the modulation signal. In a pulsed mode of operation of a pulsed DC signal, the voltage, current, or power signal may be a periodic or non-periodic DC signal that alternates between a first amplitude and a second amplitude over one or more cycles and modulated by a modulation signal in order to define an envelope for the pulsed DC signal. In various configurations, a transition between the first amplitude and the second amplitude may include various shapes, including vertical slopes, non-vertical slopes, or combinations thereof, stair steps, and the like. Further the transition between the first amplitude and the second, or the second amplitude and the first amplitude, may be consistent or vary from cycle.

In a typical power supply configuration, output voltage, current, or power applied to the load is determined using sensors that measure the forward and reflected voltage, current, or power signal. Either set of these signals is analyzed in a control loop. The analysis typically determines a parameter or cost function that varies in accordance with voltage, current, or power and is used to adjust the output of the power supply in order to vary the voltage, current, or power applied to the load. In a power delivery system where the load is a process chamber or other non-linear or time-varying load, the varying impedance of the load causes a corresponding varying of voltage, current, or power applied to the load and consequent varying of the parameter or cost function, as applied voltage, current, or power is in part a function of the impedance of the load.

In systems where fabrication of various devices relies upon introduction of voltage, current, or power to a load to control a fabrication process, voltage, current, or power is typically delivered in one of two configurations. In a first configuration, voltage, current, or power is capacitively coupled to the load. Such systems are referred to as capacitively coupled plasma (CCP) systems. In a second configuration, the voltage, current, or power is inductively coupled to the load. Such systems are typically referred to as inductively coupled plasma (ICP) systems. Coupling to the plasma can also be achieved via wave coupling at microwave frequencies. Such an approach typically uses Electron Cyclotron Resonance (ECR) or microwave sources. Helicon sources are another form of wave coupled sources and typically operate at frequencies similar to that of conventional ICP and CCP systems. In various configurations, the Helicon sources may operate at RF frequencies. Power delivery systems may include at least one bias power and/or a source power applied to one or a plurality of electrodes of the load. The source power typically generates a plasma and controls plasma density, and the bias power modulates ions in the formulation of the sheath. The bias and the source may share the same electrode or may use separate electrodes, in accordance with various design considerations.

When a power delivery system drives a time-varying or non-linear load, such as a process chamber or plasma chamber, the power absorbed by the bulk plasma and plasma sheath results in a density of ions with a range of ion energy. One characteristic measure of ion energy is the ion energy distribution function (IEDF). The ion energy distribution function (IEDF) can be controlled with the bias power or voltage. One way of controlling the IEDF for a system in which multiple voltage, current, or power signals are applied to the load occurs by varying multiple voltage, current, or power signals that are related by at least one of amplitude, frequency, and phase. The related at least one of amplitude, frequency, and phase of multiple voltage, current, or power signals may also be related by a Fourier series and the associated coefficients. The frequencies between the multiple voltage, current, or power signals may be locked, and the relative phase between the multiple voltage, current, or signals may also be locked. Examples of such systems can be found with reference to U.S. Pat. No. 7,602,127, issued Oct. 13, 2009; U.S. Pat. No. 8,110,991, issued Feb. 7, 2012; and U.S. Pat. No. 8,395,322, issued Mar. 12, 2013, all entitled Phase and Frequency Control of a Radio Frequency Generator from an External Source, assigned to the assignee of the present application, and incorporated by reference herein.

Time varying or non-linear loads may be present in various applications. In one application, plasma processing systems may also include components for plasma generation and control. One such component is a non-linear load implemented as a process chamber, such as a plasma chamber or reactor. A typical plasma chamber or reactor utilized in plasma processing systems, such as by way of example, for thin-film manufacturing, can utilize a dual power system. One voltage, current, or power generator (the source) controls the generation of the plasma, and the other voltage, current, or power generator (the bias) controls ion energy. Examples of dual power systems include systems that are described in U.S. Pat. Nos. 7,602,127; 8,110,991; and 8,395,322, referenced above. The dual power system described in the above-referenced patents employs a closed-loop control system to adapt power supply operation for the purpose of controlling ion density and its corresponding ion energy distribution function (IEDF).

Multiple approaches exist for controlling a process chamber, such as may be used for generating plasmas. For example, in voltage, current, or power delivery systems, phase and frequency of multiple driving signals operating at the same or nearly the same frequency may be used to control plasma generation. For such driven plasma sources, the periodic waveform affecting plasma sheath dynamics and the corresponding ion energy are generally known and are controlled by the frequency of the periodic waveforms and the associated phase interaction. Another approach in voltage, current, or power delivery systems involves dual frequency control. That is, two frequency sources operating at different frequencies are used to power a plasma chamber to provide substantially independent control of ion and electron densities. In various configurations, the frequency may be a RF frequency.

Another approach utilizes wideband RF power sources to drive a plasma chamber. A wideband approach presents certain challenges. One challenge is coupling the power to the electrode. A second challenge is that the transfer function of the generated waveform to the actual sheath voltage for a desired IEDF must be formulated for a wide process space to support material surface interaction. In one responsive approach in an inductively coupled plasma system, controlling power applied to a source electrode controls the plasma density while controlling power applied to the bias electrode modulates ions to control the IEDF to provide etch rate and etch feature profile control. By using source electrode and bias electrode control, the etch rate and other various etch characteristics are controlled via the ion density and energy.

As integrated circuit and device fabrication continues to evolve, so do the power requirements for controlling the process for fabrication. For example, with memory device fabrication, the requirements for bias voltage, current, or power continue to increase. Increased voltage, current, or power generates higher and more energetic ions for increased directionality or anisotropic etch feature profiles and faster surface interaction, thereby increasing the etch rate and allowing higher aspect ratio features to be etched. In one non-limiting example, in some voltage, current, or power delivery systems, increased ion energy is sometimes accompanied by a lower bias frequency requirement along with an increase in the power and number of bias power sources coupled to the plasma sheath created in the plasma chamber. The increased power at a lower bias frequency and the increased number of bias power sources results in intermodulation distortion (IMD) from sheath modulation. The IMD emissions can significantly reduce power delivered by the source where plasma generation occurs. U.S. Pat. No. 10,821,542, issued Nov. 3, 2020, entitled Pulse Synchronization by Monitoring Power in Another Frequency Band, assigned to the assignee of the present application, and incorporated by reference herein, describes a method of pulse synchronization by monitoring power in another frequency band. In the referenced U.S. patent application, the pulsing of a second RF generator is controlled in accordance with detecting at the second RF generator the pulsing of a first RF generator, thereby synchronizing pulsing between the two RF generators.

In more specific instances of integrated circuit and device fabrication, the manufacture of high performance memory devices such as three dimensional NAND (3D NAND) flash memory and Dynamic Random Access Memory (DRAM) requires precise etching of extremely high aspect ratio (HAR) features. HAR features typically have a height to width ratio (height: width) ratio of greater than 50:1 (>50:1). In order to manufacture high performance memory devices described herein, a bias power source is configured to output a high voltage, current, or power, pulsed DC signal or waveform. The pulsed DC bias waveform is used to create a monoenergetic IEDF. The modulation of this waveform is used to alternate between high energy ion-assisted etching of the memory structure and low energy polymer formation to protect the HAR feature sidewalls. A lower energy or lower amplitude pulsed DC bias waveform may be used for precision etching of logic structures, such as Shallow Trench Isolation (STI) and Gate All-Around (GAA) structures.

As described in greater detail below, varying the bias voltage causes a modulation of the plasma sheath thickness and, thus, the plasma sheath capacitance. Plasma sheath capacitance modulation causes rapid fluctuations of the source generator load impedance and rapid changes in reflected power. Rapid changes in reflected power reduce power delivered to the plasma chamber or load and also increase electrical and thermal stresses on the source generator.

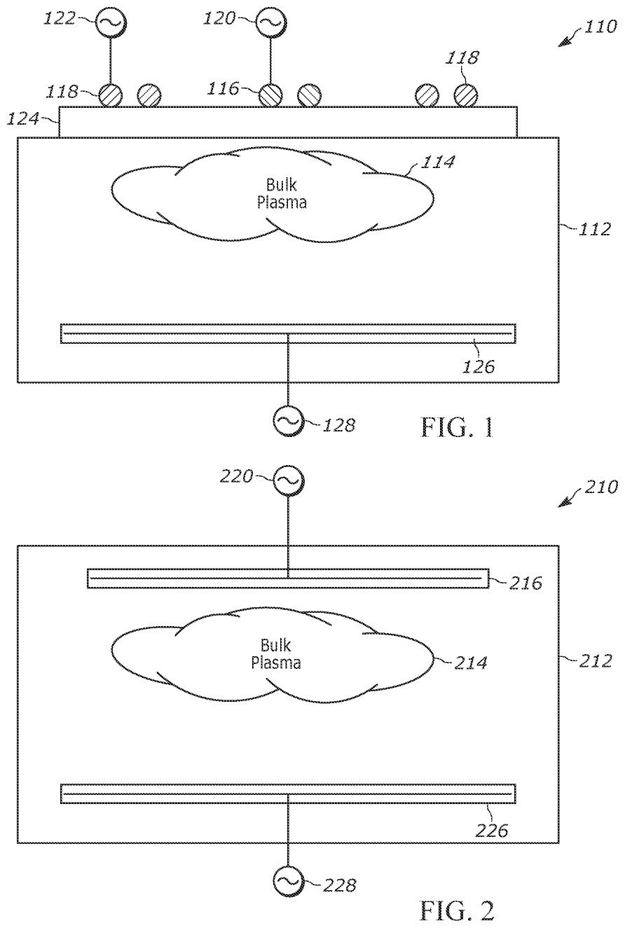

FIG. 1 depicts a representation of an inductively coupled plasma (ICP) system 110. ICP system 110 includes a non-linear load, such as a reactor, plasma reactor, or plasma chamber 112, which will be referred to interchangeably herein, for generating plasma 114. Energy in the form of voltage, current, or power signals is applied to plasma chamber 112 via a pair of coils, including a coil assembly that in various configurations includes one or multiple coils arranged in various configurations. In one non-limiting arrangement shown in FIG. 1, plasma chamber 112 includes one or both a first coil 116 and a second coil 118. In various configurations, multiple coils may be arranged concentrically, intertwined, or in a spiral configuration. Voltage, current, or power is applied to first coil 116 via voltage, current, or power source, RF power generator, or RF power source 120, and voltage, current, or power is applied to second coil 118 via voltage, current, or power source, RF power generator, or RF power source 122. Coils 116 and 118 are arranged to provide voltage, current, or power to plasma chamber 112. A dielectric window 124 enables voltage, current, or power to couple through to the plasma while providing a vacuum seal. A substrate 126 is placed in plasma chamber 112 and typically forms the work piece that is the subject of plasma operations. A voltage, current, or power supply; voltage, current, or power source; RF power generator; or RF power source 128 (the terms may be used herein interchangeably to refer to an appropriately configured voltage, current, or power supply, source, or generator) applies power to plasma chamber 112 via substrate 126.

In various configurations, power sources 120, 122 provide a source voltage, current, or power to ignite or generate plasma 114 or control the plasma density. Also in various configurations, power source 128 provides a bias voltage, current, or power that modulates the ions to control the ion potential or ion energy of the plasma 114. In various configurations, power sources 120, 122 are locked to operate at the same frequency and voltage, current, or power, with fixed or varying relative phases. In various other configurations, power sources 120, 122 may operate at different frequencies, voltages, currents, or powers, and relative phases.

FIG. 2 depicts a representation of a capacitively coupled plasma (CCP) system 210. CCP system 210 includes plasma chamber 212 for generating plasma 214. A pair of electrodes 216, 226 placed within plasma chamber 212 connect to respective DC (ω=0) power sources or RF power generators 220, 228, which may generate a DC signal or other voltage, current, or power signals having one or more of varying amplitude, frequency, or duty cycle, including, but not limited to, a RF signal. In various configurations, power source 220 provides a source voltage, current, or power to ignite or generate plasma 214 or control the plasma density, although a bias power source may also be used to ignite a plasma. In various configurations, power source 228 provides a bias voltage, current, or power that modulates the ions in the plasma to control ion potential, ion energy, or ion density of the plasma 214. In various CCP configurations, bias voltage, current, or power and source voltage, current, or power may be applied to the upper electrode, such as electrode 216, and the lower electrode, such as electrode 226, in various combinations. In another non-limiting example, bias voltage, current, or power and source voltage, current, or power may be applied to a lower electrode, such as electrode 226, and the top electrode, such as electrode 216, is grounded or floating. In various configurations, power sources 220, 228 operate at relative phases when the sources are harmonically related. In various other configurations, power sources 220, 228 operate at different frequencies and voltages, currents, or powers, with fixed or varying relative phases. Also in various configurations, power sources 220, 228 can be connected to the same electrode, while the counter electrode is connected to ground or to yet a third DC (ω=0), or other voltage, current, or sources having one or more of a varying amplitude, frequency, or duty cycle power generator (not shown), including, but not limited to, a RF signal.

In addition to a sinusoidal bias waveform, in various configurations, a non-sinusoidal bias waveform may control ion energy. By way of non-limiting example, the bias waveform may be a RF waveform, a pulsed RF waveform, a DC waveform, a pulsed DC waveform, a pulsed rectangular waveform, or a piecewise linear waveform as described in U.S. Pat. No. 10,396,601, issued on Aug. 27, 2019, entitled Piecewise RF Power Systems and Methods for Supplying Pre-Distorted RF Bias Voltage Signals to an Electrode in a Processing Chamber, assigned to the assignee of the present application, and incorporated by reference herein. In various configurations, the bias waveform may be any of a voltage, current, or power waveform having one or more of a varying amplitude, frequency, or duty cycle. In various configurations, a radio frequency (RF) signal may be considered as having a frequency in the range of approximately 2 kHz to 300 GHz.

FIG. 3 depicts a cross-sectional view of a generalized representation of a dual voltage, current, or power input plasma system 310. Plasma system 310 includes first electrode 312 connected to ground 314 and second electrode 316 spaced apart from first electrode 312. A first power source 318 generates a first voltage, current, or power signal as described above applied to second electrode 316 at a first frequency f=ω₁. A second power source 320 generates a second DC (ω=0) or sinusoidal voltage, current, or power applied to second electrode 316. In various configurations, second power source 320 operates at a second frequency f=ω₂, where ω₂=nω that is the n^{th} harmonic frequency of the frequency of first power source 318. In various other configurations, second power source 320 operates at a frequency that is not a multiple of the frequency of the first power source 318.

Coordinated operation of respective power sources 318, 320 results in generation and control of plasma 322. As shown in FIG. 3 in schematic view, plasma 322 is formed within an asymmetric sheath 330 of plasma chamber 324. Sheath 330 includes a ground or grounded sheath 332 and a powered sheath 334. A sheath is generally described as the surface area surrounding plasma 322. As can be seen in schematic view in FIG. 3, grounded sheath 332 has a relatively large surface area 326. Powered sheath 334 has a small surface area 328. Because each sheath 332, 334 functions as a dielectric between the conductive plasma 322 and respective electrodes 312, 316, each sheath 332, 334 forms a capacitance between plasma 322 and respective electrodes 312, 316.

As will be described in greater detail herein, in systems in which a high frequency voltage, current, or power source, such as second power source 320, and a low frequency voltage, current, or power source, such as first power source 318, intermodulation distortion (IMD) products are introduced. IMD products result from a change in plasma sheath thickness, thereby varying the capacitance between plasma 322 and electrode 312, via grounded sheath 332, and plasma 322 and electrode 316, via powered sheath 334. The variation in the capacitance of powered sheath 334 generates IMD. Variation in powered sheath 334 has a greater impact on the capacitance between plasma 322 and electrode 316 and, therefore, on the reverse IMD emitted from plasma chamber 324. In some plasma systems grounded sheath 332 acts as a short circuit and is not considered for its impact on reverse IMD.

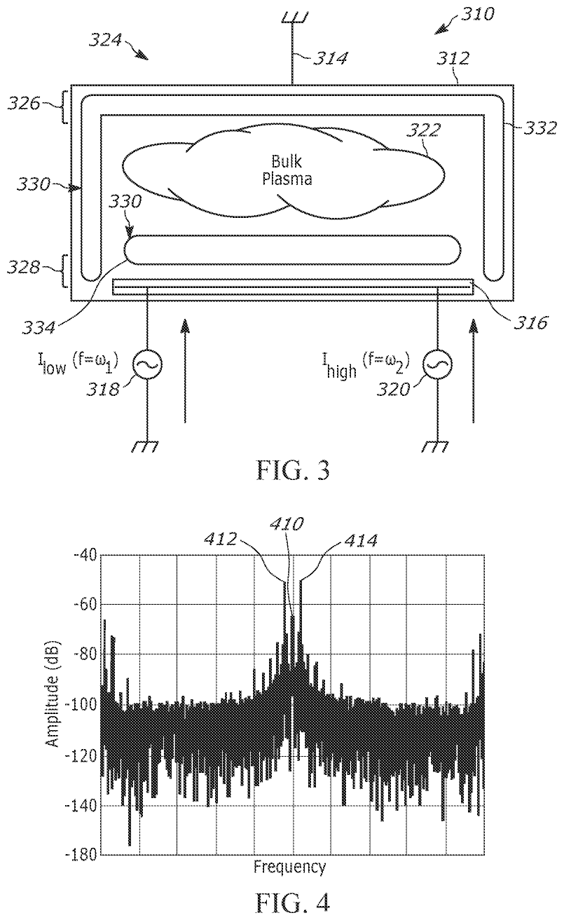

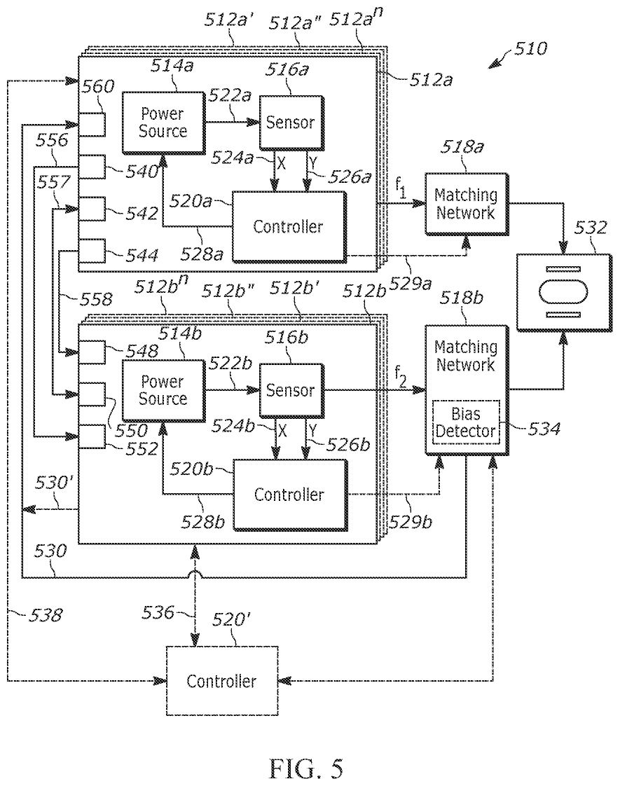

FIG. 4 shows a plot of amplitude versus frequency for an exemplary voltage, current, or power delivery system having a low frequency source such as first power source 318, and a high frequency source, such as second power source 320. FIG. 4 shows amplitude of the reflected energy with respect to frequency for power source 320. FIG. 4 includes a center peak 410 indicating the center frequency of operation of the high frequency power source, such as second power source 320 of FIG. 3. On either side of center peak 410, FIG. 4 also shows IMD components 412, 414 which represent the IMD introduced by the application of energy from a low frequency power source, such as first power source 318 of FIG. 3. By way of non-limiting example, if second power source 320 operates at a frequency of 60 MHz, and low frequency power source 318 operates at 400 kHz, IMD components can be found at 60 MHz+/−n*400 kHz, where n is any integer. Thus, peaks of IMD components 412, 414 represent the high frequency +/− the low frequency of the respective power supplies. Driving an electrode at multiple harmonics, such as shown in FIG. 3, provides the opportunity to control DC self-bias electrically and to tailor the energetic levels of ion density.

FIG. 5 depicts a RF generator or power supply system 510. Power supply system 510 includes a pair of radio frequency (RF) generators or power supplies 512a, 512b, matching networks 518a, 518b, and load 532, such as a non-linear load, which may be a plasma chamber, plasma reactor, process chamber, and the like. In various configurations, generator 512a is referred to as a source generator or power supply, and matching network 518a is referred to as a source matching network. Further, in various configurations, one or both of voltage current, or power generators or power supplies 512a, 512b may output a continuous or pulsed time-varying voltage, current, or power signal or a continuous or pulsed DC voltage, current, or power signal. Also in various configurations, generator 512b is referred to as a bias generator or power supply, and matching network 518b is referred to as a bias matching network. It will be understood that components can be referenced individually or collectively using the reference number with or without a letter subscript or a prime symbol. In various configurations, one or both of matching networks 518a, 518b may be implemented as a RF blocking filter, rather than an impedance match, such as may be the case for a matching network receiving a pulsed DC or non-sinusoidal signal. In various other configurations, one or both of matching networks 518a, 518b may be omitted.

In various configurations, source generator 512a receives a control signal 530 from matching network 518b, generator 512b, or a control signal 530′ from bias generator 512b. Control signals 530 or 530′ represent an input signal to source generator 512a that indicates one or more operating characteristics or parameters of bias generator 512b. In various configurations, a synchronization bias detector 534 senses the signal output from matching network 518b to load 532 and outputs synchronization or trigger signal 530 to source generator 512a. In various configurations, synchronization or trigger signal 530′ may be output from bias generator 512b to source RF generator 512a, rather than trigger signal 530. A difference between trigger or synchronization signals 530, 530′ may result from the effect of matching network 518b, which can adjust the phase between the input signal to and output signal from matching network. Signals 530, 530′ include information about the operation of bias RF generator 512b that in various configurations enables predictive responsiveness to address periodic fluctuations in the impedance of plasma chamber or load 532 caused by the bias generator 512b. When control signals 530 or 530′ are absent, generators 512a, 512b operate autonomously.

Generators 512a, 512b include respective power sources or amplifiers 514a, 514b, sensors 516a, 516b, and processors, controllers, or control modules 520a, 520b. Power sources 514a, 514b generate respective voltage, current, or power signals 522a, 522b, various configurations of which are described above, output to respective sensors 516a, 516b. RF power signals 522a, 522b. Signals 522a, 522b pass through sensors 516a, 516b and are provided to matching networks 518a, 518b as respective power signals f₁ and f₂. Sensors 516a, 516b output signals that vary in accordance with various parameters sensed from load 532. While sensors 516a, 516b, are shown within respective generators 512a, 512b, sensors 516a, 516b can be located externally to generators 512a, 512b. Such external sensing can occur at the output of the generator, at the input of an impedance matching device located between the generator and the load, or between the output of the impedance matching device (including within the impedance matching device) and the load.

Sensors 516a, 516b detect various operating parameters and output signals X and Y. Sensors 516a, 516b may include voltage, current, and/or directional coupler sensors. Sensors 516a, 516b may detect (i) voltage V and current I and/or (ii) forward power P_{FWD} output from respective power amplifiers 514a, 514b and/or RF generators 512a, 512b and reverse or reflected power P_{REV} received from respective matching networks 518a, 518b or load 532 connected to respective sensors 516a, 516b. The voltage V, current I, forward power P_{FWD}, and reverse power P_{REV} may be scaled, filtered, or scaled and filtered versions of the actual voltage, current, forward power, and reverse power associated with the respective power sources 514a, 514b. Sensors 516a, 516b may be analog or digital sensors or a combination thereof. In a digital implementation, the sensors 516a, 516b may include analog-to-digital (A/D) converters and signal sampling components with corresponding sampling rates. Signals X and Y can represent any of the voltage V and current I or forward (or source) power P_{FWD} reverse (or reflected) power P_{REV}.

Sensors 516a, 516b generate sensor signals X, Y, which are received by respective controllers or control modules 520a, 520b. Control modules 520a, 520b process the respective X, Y signals 524a, 526a and 524b, 526b and generate one or a plurality of feedforward or feedback control signals 528a, 528b to respective power sources 514a, 514b. Power sources 514a, 514b adjust voltage, current, or power signals 522a, 522b based on the received one or plurality feedback or feedforward control signal. In various configurations, control modules 520a, 520b may control matching networks 518a, 518b, respectively, via respective control signals 529a, 529b based on, for example, X, Y signals 524a, 526a and 524b, 526b. Control modules 520a, 520b may include one or more proportional-integral (PI), proportional-integral-derivative (PID), linear-quadratic-regulator (LQR) controllers or subsets thereof and/or direct digital synthesis (DDS) component(s) and/or any of the various components described below in connection with the modules.

In various configurations, control modules 520a, 520b may include functions, processes, processors, or submodules. Control signals 528a, 528b may be control or actuator drive signals and may communicate DC offset or rail voltage, voltage or current magnitude, frequency, and phase components, and the like. In various configurations, feedback control signals 528a, 528b can be used as inputs to one or multiple control loops. In various configurations, the multiple control loops can include a proportional-integral (PI), proportional-integral-derivative (PID) controllers, linear-quadratic-regulator (LQR) control loops, or subsets thereof, for RF drive, and for power supply rail voltage. In various configurations, control signals 528a, 528b can be used in one or both of a single-input-single-output (SISO) or multiple-input-multiple-output (MIMO) control scheme. An example of a MIMO control scheme can be found with reference to U.S. Pat. No. 10,546,724, issued on Jan. 28, 2020, entitled Pulsed Bidirectional Radio Frequency Source/Load, assigned to the assignee of the present application, and incorporated by reference herein. In other configurations, signals 528a, 528b can provide feedforward control as described in U.S. Pat. No. 10,049,857, issued Aug. 14, 2018, entitled Adaptive Periodic Waveform Controller, assigned to the assignee of the present application, and incorporated by reference herein.

In various configurations, power supply system 510 can include controller 520′. Controller 520′ may be disposed externally to either or both of generators 512a, 512b and may be referred to as external or common controller 520′. In various configurations, controller 520′ may implement one or a plurality of functions, processes, or algorithms described herein with respect to one or both of controllers 520a, 520b. Accordingly, controller 520′ communicates with respective generators 512a, 512b via a pair of respective links 536, 538 which enable exchange of data and control signals, as appropriate, between controller 520′ and generators 512a, 512b. For the various configurations, controllers 520a, 520b, 520′ can distributively and cooperatively provide analysis and control of generators 512a, 512b. In various other configurations, controller 520′ can provide control of generators 512a, 512b, eliminating the need for the respective local controllers 520a, 520b.

In various configurations, power source 514a, sensor 516a, controller 520a, and matching network 518a can be referred to as source RF power source 514a, source sensor 516a, source controller 520a, and source matching network 518a, respectively. Similarly in various configurations, RF power source 514b, sensor 516b, controller 520b, and matching network 518b can be referred to as bias power source 514b, bias sensor 516b, bias controller 520b, and bias matching network 518b, respectively. In various configurations and as described above, the source term refers to the generator or voltage, current, or power source that generates a plasma, and the bias term refers to the generator or voltage, current, or power source that tunes ion potential and the Ion Energy Distribution Function (IEDF) of the plasma. In various configurations, the source and bias power supplies operate at different frequencies or duty cycles. In various configurations, the source power supply operates at a higher frequency or duty cycle than the bias power supply. In various other configurations, the source and bias power supplies operate at the same frequencies or duty cycles or substantially the same frequencies or duty cycles.

According to various configurations, in addition to or by way of partial or total substitution to the synchronization signals described above with respect to signals 530, 530′, source generator 512a and bias generator 512b include multiple ports to communicate with each other and with external devices. Source generator 512a includes pulse synchronization port 540, communication port 542, RF port 544, and control signal port 560. Bias generator 512b includes RF port 548, communication port 550, and pulse synchronization port 552. Pulse synchronization port 540 of source generator 512a communicates pulse synchronization signals via link 556 with pulse synchronization port 552 of bias generator 512b. Communication port 542 of source generator 512a and communication port 550 of bias generator 512b communicate data and information via a communication link 557. RF port 544 of source generator 512a communicates with RF port 548 via communication link 558. Control signal port 560 of source generator 512a receives one or both of control signals 530, 530′, as described above. In various configurations, one or more of the ports described above may communicate with matching network 518 for communicating sensed or control signals, as may be described herein.

In various configurations, communication between pulse synchronization port 540 and pulse synchronization port 552 may be unidirectional or bidirectional between source generator 512a and bias generator 512b. In various configurations, one of source generator 512a and bias generator 512b communicate, by way of non-limiting example, envelope pulse information to the other of bias generator 512b and source generator 512a. In various configurations, one or multiple communication links 556 link pulse synchronization port 540 and pulse synchronization port 552. In various configurations, communication between pulse synchronization port 540 and pulse synchronization port 552 may occur via analog or digital communication.

In various configurations, communication between communication port 542 of source generator 512a and communication port 550 of bias generator 512b may be unidirectional or bidirectional between source generator 512a and bias generator 512b. In various configurations, communication port 542 of source generator 512a and communication port 550 of bias generator 512b communicate, by way of non-limiting example, data, information, or synchronization signals. In various configurations, one or multiple communication links 557 link pulse synchronization port 542 and pulse synchronization port 550 In various configurations, communication between pulse synchronization port 542 and pulse synchronization port 550 may occur via analog or digital communication.

In various configurations, communication between RF port 544 of source generator 512a and RF port 548 of bias generator 512b may be unidirectional or bidirectional between source generator 512a and bias generator 512b. In various configurations, RF port 544 of source generator 512b and RF port 548 of bias generator 512b communicate, by way of non-limiting example, a signal indicating one or more of voltage, current, or power output by the respective generator. By way of non-limiting example, time-varying RF signals, such as sinusoidal voltage, current, or power signals may be communicated. In various configurations, one or multiple communication links 558 link signal port 544 and signal port 548. In various configurations, communication between signal port 544 and signal port 548 may occur via analog or digital communication.

In various configurations, a control signal communicated via communications link 558 is substantially the same as the control signal controlling source generator 512a. In various other configurations, the control signal communicated via communications link 558 is the same as the control signal controlling source generator 512a, but is phase shifted within source generator 512a in accordance with a requested phase shift generated by bias generator 512b. Thus, in various configurations, source generator 512a and bias generator 512b are driven by substantially identical control signals or by substantially identical control signals phase shifted by a predetermined amount.

In various configurations, power supply system 510 may include multiple source generators 512a and multiple bias generators 512b. By way of non-limiting example, a plurality of source generators 512a, 512a′, 512a″, . . . , 512aⁿ can be arranged to provide a plurality of output power signals to one or more source electrodes of load 532. Similarly, a plurality of bias generators 512b, 512b′, 512b″, . . . , 512bⁿ may provide a plurality of output power signals to a plurality of bias electrodes of load 532. When source generator 512a and bias generator 512b are configured to include a plurality of respective source generators or bias generators, each generator will output a separate signal to a corresponding plurality of matching networks 518a, 518b, configured to operate as described above, in a one-to-one correspondence. In various other configurations, there may not be a one-to-one correspondence between each generator and matching network. In various configurations, multiple source electrodes may refer to multiple electrodes that cooperate to define a composite source electrode. Similarly, multiple bias electrodes may refer to multiple connections to multiple electrodes that cooperate to define a composite bias electrode.

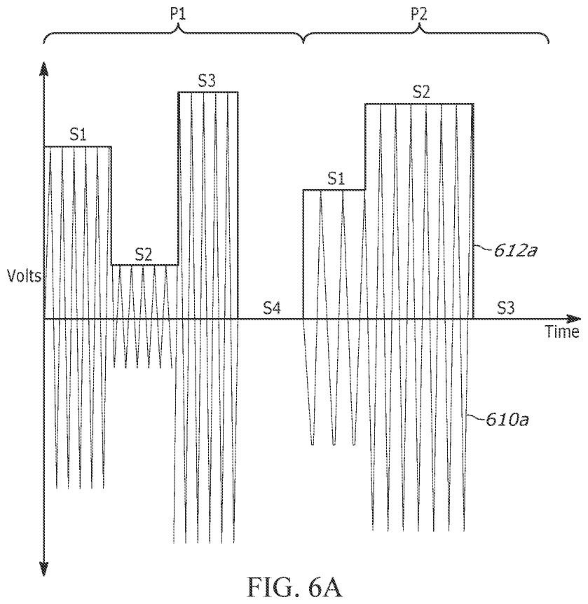

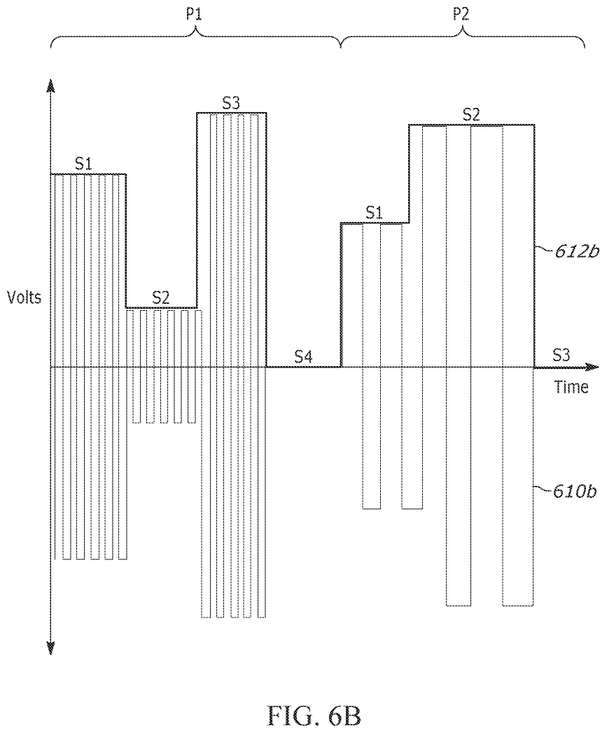

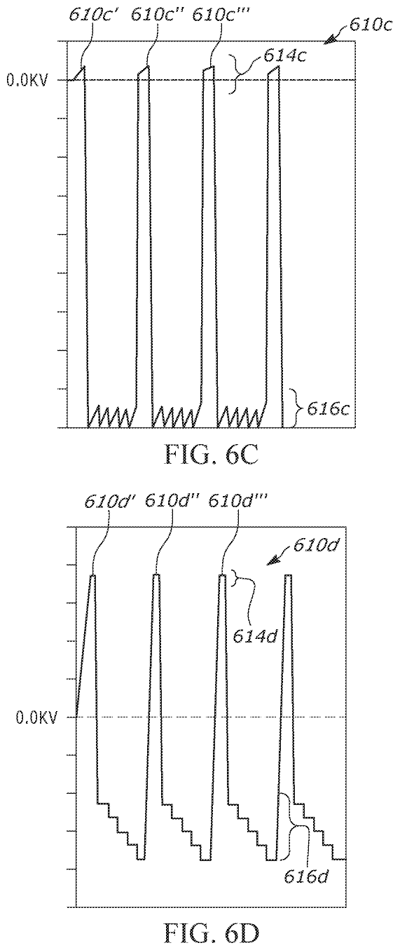

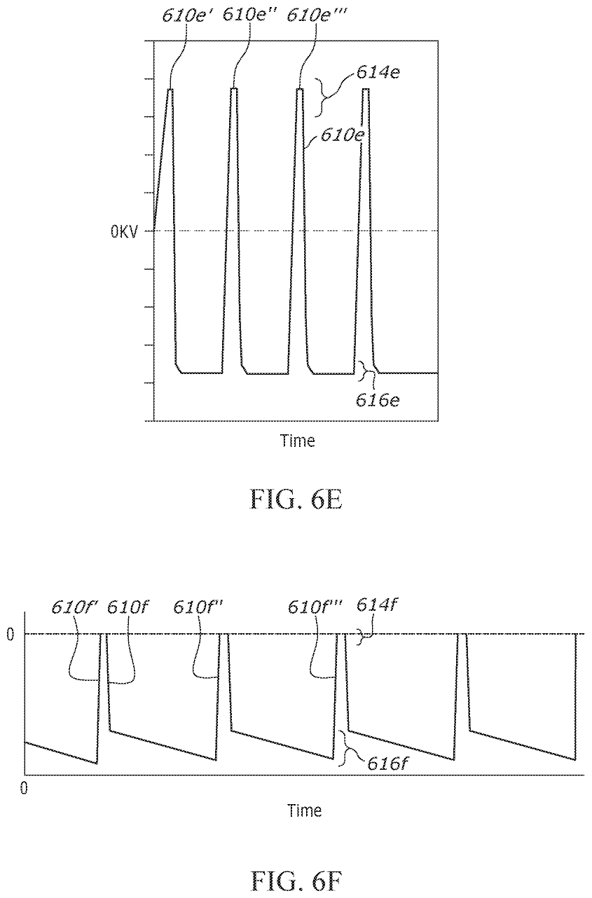

FIG. 6A depicts a plot of voltage versus time to describe a pulse or pulsed mode of operation for delivering voltage, current, or power to a load, such as load 532 of FIG. 5. More particularly, FIG. 6A depicts signal or waveform 610a, which, by way of non-limiting example, is depicted as a sinusoidal signal or waveform. Waveform 610a may be referred to as a carrier waveform or carrier signal. Two-multistate pulses P1, P2 of an envelope or pulse signal 612a having respective states S1-S4 and S1-S3 modulate waveform 610a. As shown at states S1-S3 of P1 and S1-S2 of P2, when the pulses are ON, RF generator 512 outputs RF signal as waveform 610a having an amplitude defined by the pulse magnitude of each state. Conversely, during states S4 of P1 and S3 of P2, the pulses are OFF, and generator 512 does not output waveform 610a. Pulses P1, P2 can repeat at a constant duty cycle or a variable duty cycle, and states S1-S4, S1-S3 of each respective pulse P1, P2 may have the same or varying amplitudes and widths. In various configurations, waveform 610a may be implemented as a RF or other than RF waveform and may be a sinusoidal or non-sinusoidal waveform. Further, the frequency of waveform may vary between or within states S1-S4, S1-S3 and between or within pulses P1, P2.

FIG. 6B depicts a plot of voltage versus time to describe an alternative pulse or pulsed mode of operation for delivering voltage, current, or power to a load, such as load 532 of FIG. 5. FIG. 6B depicts signal or waveform 610b, which, by way of non-limiting example, is depicted as a square wave signal or waveform. Waveform 610b may be referred to as a pulsed DC signal or waveform or a DC carrier signal or waveform. Two-multistate pulses P1, P2 of an envelope or pulse signal 612b having respective states S1-S4 and S1-S3 modulate waveform 610b. Waveform 610b is shown as a non-sinusoidal, periodic signal or waveform modulated by pulses P1 and P2. Waveform 610b may be a signal that pulses or oscillates between a first amplitude and a second amplitude over one or more cycles with various transitions therebetween. At least one of the first and second amplitudes may vary over time in accordance with envelope or pulse signal 612b. As shown at states S1-S3 of P1 and S1-S2 of P2, when the pulses are ON, RF generator 512 outputs waveform 610b having an amplitude defined by the pulse magnitude of each state. Conversely, during states S4 of P1 and S3 of P2, the pulses are OFF, and generator 512 does not output waveform 610b. Thus, modulating signal or waveform 610b (pulsed DC signal or waveform) with envelope or pulse signal 612b provides a pulse-within-a-pulse effect. Pulses P1, P2 can repeat at a constant duty cycle or a variable duty cycle, and states S1-S4, S1-S3 of each respective pulse P1, P2 may have the same or varying amplitudes and widths. In various configurations, while waveform 610b of FIG. 6B is shown as a square wave, waveform 610b need not be implemented as a conventional square wave. The first and second amplitudes of waveform 610b may be flat, sloping, or peaked, and the transitions between the first and second amplitudes may include linear slopes, stairsteps, other shapes, or combinations thereof.

FIG. 6C shows one non-limiting example of a pulsed DC carrier signal 610c having cycles 610c′, 610c″, 610c′″. Pulsed DC signal 610c includes high amplitudes 614c of cycles 610c′, 610c″, 610c′″ and low amplitude 616c of cycles 610c′, 610c″, 610c′″. As shown in FIG. 6C, high amplitudes 614c include a sloping transition to a peak. Low amplitudes 616c have a sawtooth appearance, which may result from multiple power amplifiers transitioning negative or low substantially simultaneously.

FIG. 6D shows one non-limiting example of a pulsed DC carrier signal 610d having cycles 610d′, 610d″, 610d″. Pulsed DC signal 610d includes high amplitudes 614d of cycles 610d′, 610d″, 610d′″ and low amplitudes 616d of cycles 610d′, 610d″, 610d′″. As shown in FIG. 6D, high amplitudes 614d are generally flat. Low amplitudes 616d have a stairstep transition, which may result from selected power amplifiers transitioning negatively or low sequentially. In various configurations, the stairstep transition of low amplitudes 616d provides improved slope compensation.

FIG. 6E shows one non-limiting example of a pulsed DC carrier signal 610e having cycles 610e′, 610e″, 610e″. Pulsed DC signal 610e includes high amplitude 614e of cycles 610e′, 610e″, 610e′″ and low amplitudes 616e of cycles 610e′, 610e″, 610e′″. As shown in FIG. 6E, high amplitudes 614e are generally flat. Low amplitudes 616e have a rounded shape at the transition from descending to generally constant, which may result from selected power amplifiers transitioning negatively or low sequentially with limited delay between each power amplifier transition. In various configurations, the pattern of low amplitudes 616e may improve ringing and overshoot.

FIG. 6F shows one non-limiting example of a pulsed DC carrier signal 610f having cycles 610f, 610f′, 610f″. Pulsed DC signal 610f includes high amplitudes 614f of cycles 610f, 610f′, 610f″ and low amplitudes 616f of cycles 610f, 610f″, 610f′″. As shown in FIG. 6F, high amplitudes 614f are generally constant. Low amplitudes 616f include a linear transition which results from piecewise linear control of DC carrier signal 610f. By way of non-limiting example, in various configurations, DC carrier signal 610f may be a piecewise linear waveform as described in U.S. Pat. No. 10,396,601.

In various configurations, pulse signal 612 may be other than a square wave as shown in FIGS. 6A, 6B. Further, by way of non-limiting example, envelope or pulse signal 612 may be a single or multistate rectangular, trapezoidal, triangular, sawtooth, gaussian, or other shape that defines an envelope or modulating envelope of the underlying, modulated, carrier signal 610.

In various configurations, carrier signal 610 may occur or reoccur periodically or non-periodically within fixed or variable periods or time periods. In various other configurations, carrier signal 610 may vary in shape between each occurrence. Signal 610 may operate at frequencies that vary between states or within a state. In various other configurations, pulse signal 612 may occur or reoccur within fixed or variable time periods and vary in shape between each occurrence. Further yet, pulses P1, P2 can have multiple states S1, . . . , Sn of varying amplitude, duration, and shape. States S1, . . . , Sn may repeat within fixed or variable periods and may include all or a portion of the various shapes described above.

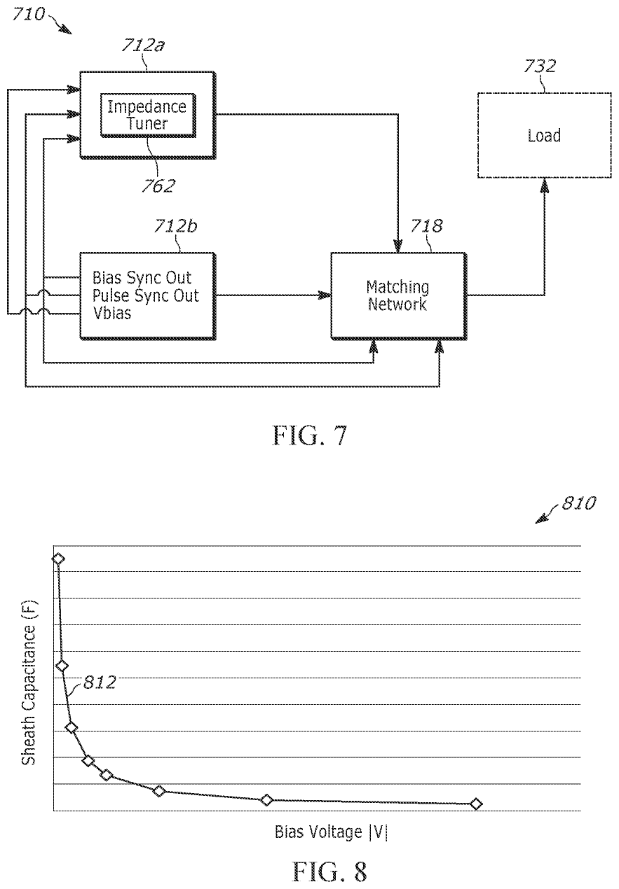

FIG. 7 shows a portion of a power delivery system 710 arranged similarly as described above with respect to FIG. 5. Power delivery system 710 includes generator 712a, which may be referred to as a source generator, and generator 712b, which may be referred to as a bias generator, both as described above. In various configurations, bias generator 712b is configured as a pulsed DC bias generator that generates a DC signal that is selectively turned on and off to provide a pulsed DC output signal.

Bias generator 712b communicates with source generator 712a and matching network 718. Bias generator 712b communicates a bias sync output signal and a pulse sync output signal to source generator 712a and matching network 718. Bias generator 712b also communicates a V_{bias} signal to source generator 712a. The bias sync output signal communicated by generator 712b indicates a position in time of the bias signal (the carrier signal 610 of FIGS. 6A-6F) and may be used as a synchronization signal. In various configurations, the bias sync output signal indicates a leading edge of the bias signal, but can indicate a trailing edge or intermediate position of the bias signal. The pulse sync output signal indicates a position in time of the bias envelope period (the envelope or pulse signal 612 of FIGS. 6A-6B). In various configurations, the pulse sync output signal indicates a leading edge of the bias pulse, but can indicate a trailing edge or intermediate position of the bias pulse. Thus, the bias sync output signal and the pulse sync output signal provide a means for synchronization relative to the output of bias generator 712b and the pulse signal modulating the DC output signal generated by bias generator 712b. The V_{bias} signal communicated by bias generator 712b varies in accordance with the bias signal output by bias generator 712b and indicates a magnitude of the output of bias generator 712b. The bias sync output signal, the pulse sync output signal, and the V_{bias} signal may be communicated in one or both of an analog or digital format. Further, in various configurations, the bias sync output signal and the pulse sync output signal are also communicated to matching network 718.

Source generator 712a also includes an impedance tuner 762. Impedance tuner 762 provides an impedance adjustment or impedance control signal in accordance with the output of bias generator 712b. In various configurations, impedance tuner 762 tunes impedance in accordance with varying output frequency of source generator 712a by determining an output frequency or frequency offset applied to the output of source generator 712a to vary the impedance match between source generator 712a and load 732. In various configurations, impedance tuner 762 tunes impedance by commanding adjustments to one or more reactive elements of matching network 718 via one or more respective actuator commands or actuator signals to vary the impedance match. In various configurations, the reactive elements of matching network 718 may be one or both of capacitive and inductive elements. In various configurations, the reactive elements of matching network 718 may vary impedance in accordance with one or both of electrical or mechanical adjustment. Impedance tuner 762 may be implemented as a module, controller, or processor and may be standalone or may be incorporated into one or more of the above-described processors.

FIG. 8 shows a plot 810 of sheath capacitance versus bias voltage 812, shown as the absolute value of bias voltage. The x-axis of FIG. 8 is represented as the absolute value of the bias voltage, but in a typical implementation sheath capacitance decreases as the bias voltage increases in a negative direction. As can be seen in FIG. 8, as the bias voltage amplitude increases, the sheath capacitance approaches zero. Thus, as the output from generator 712b changes from large negative voltages to zero, the plasma sheath capacitance changes from low capacitance to high capacitance. The change in capacitance effects a change in impedance experienced by source generator 712a. This change in impedance experienced by source generator 712a can adversely impact power delivered to the load, such as load 732 of FIG. 7. As will be described herein, impedance tuner 762 anticipates the change in impedance in accordance with signals communicated from bias generator 712b to source generator 712a to adjust one or both of frequency of the RF signal output by source generator 712a or actuator settings communicated to matching network 718.

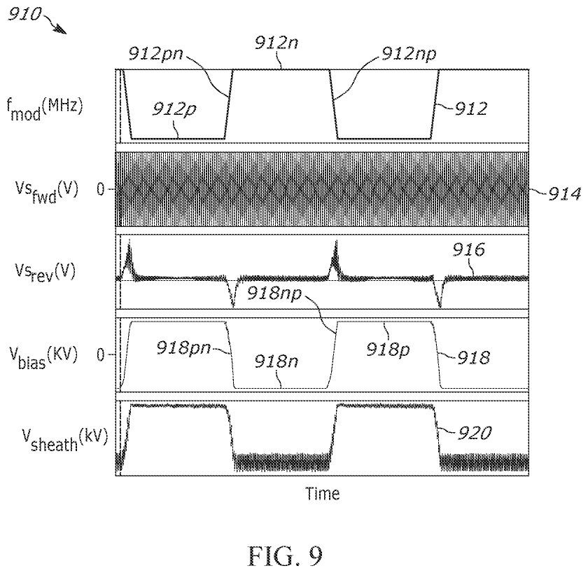

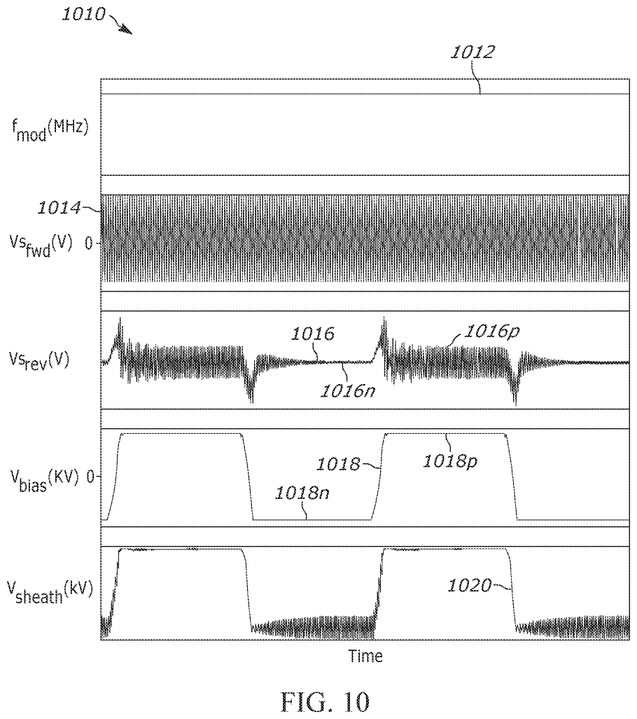

FIG. 9 shows waveforms 910 indicating operation of one various configuration of the present disclosure. Waveforms 910 include modulation frequency f_{mod} waveform 912, source generator 712a forward voltage Vs_{fwd} waveform 914, source generator 712a reverse voltage Vsᵣₑᵥ waveform 916, bias generator 712b bias voltage V_{bias} waveform 918, and sheath voltage Vₛₕₑₐₜₕ waveform 920. Forward voltage Vs_{fwd} indicates the forward voltage output from source generator 712a to the matching network, such as matching networks 518, 718. Reverse voltage Vsᵣₑᵥ indicates the reverse voltage reflected from the load, such as loads 532, 732, to source generator 712a. Bias voltage V_{bias} indicates the output of bias generator 712b. More particularly, bias waveform 918 (also referred to as the bias carrier waveform) shows two cycles of a DC carrier signal output by bias generator 712b, as described above with respect to FIG. 6. Sheath voltage Vₛₕₑₐₜₕ indicates the voltage of the plasma sheath, as described above. Modulation frequency f_{mod} indicates a frequency offset applied to the output of source generator 712a to provide frequency tuning in accordance with variation in the output of bias generator 712b. In the waveforms of FIG. 9, bias voltage V_{bias} is pulsed at a 50% duty cycle resulting in a positive half cycle 918p portion and a negative half cycle 918n portion of bias voltage V_{bias} waveform 918.

In various configurations, impedance tuner 762 of FIG. 7 determines a first impedance tuning that minimizes a sensed, measured, or determined parameter or cost function for the positive half cycle of bias voltage V_{bias} and a second impedance tuning that minimizes a sensed, measured, or determined parameter or cost function for the negative half cycle of bias voltage V_{bias}. Waveform 918 includes negative half cycle 918n and positive half cycle 918p. Since bias voltage V_{bias} waveform 918 is generally rectangular, sheath capacitance Vₛₕₑₐₜₕ waveform 920 is primarily bimodal, having a high and a low portion, and can be tuned with dual frequency modulation, as indicated by modulation frequency f_{mod} waveform 912. In various configurations, by way of non-limiting example, modulation frequency f_{mod} may be 49.3 MHz during positive half cycle 918p and 60.5 MHz during negative half cycle 918n, though it will be understood that frequencies during each respective positive half cycle and a negative half cycle will vary in accordance with the particular application. In various other configurations, impedance tuning can be achieved by varying reactive components of matching network 718 as an alternative, or in addition, to varying modulation frequency f_{mod} waveform 912.

In various configurations, impedance tuner 762 can include one or more tuners, each directed to impedance tuning over a predetermined portion of bias voltage V_{bias} waveform 918. By way of nonlimiting example, a first tuner can operate to determine a tuning frequency or reactive element adjustments for one of positive half cycle 918p or negative half cycle 918n, and a second tuner can operate to determine a tuning frequency or reactive element adjustments for the other of positive half cycle 918p or negative half cycle 918n. The respective first tuner and second tuner can operate independently, and impedance tuner 762 can synchronize operation of the first tuner and second tuner with the respective half cycles. In various configurations, bias voltage V_{bias} waveform 918 may be modulated over multiple pulse states, as described above with respect to pulse states S1-S4 of FIG. 6A, 6B. When bias voltage V_{bias} waveform 918 is modulated over multiple pulse states, impedance tuner 762 may include multiple tuners, one assigned to each pulse state. In various other configurations where bias voltage V_{bias} waveform 918 includes multiple pulse states, impedance tuner 762 may assign a tuner to one or more pulse states so that a selected tuner can operate to determine a tuning frequency or reactive element adjustments for more than one pulse state.

Although bias voltage V_{bias} waveform 918 is described above as generally rectangular, waveform 918 shows a negative slew rate during positive to negative transition 918pn and a positive slew rate during negative to positive transition 918np. The slew rate of each transition 918pn, 918np may be the same or different. The slew rates of each transition 918pn, 918np in turn result in peaks in reverse voltage Vsᵣₑᵥ waveform 916 and a slewed modulation frequency f_{mod} waveform 912, indicated at 912pn and 912np, respectively. Each slewed modulation frequency may have a slope, as can each respective, generally constant portion 912n, 912p of modulation frequency f_{mod} waveform 912. Thus, slopes m₁, m₂, m₃, m₄ correspond to respective portions 912pn, 912n, 912np, 912p of modulation frequency f_{mod} waveform 912. In various configurations, in addition to impedance tuning over generally constant portions 912p and 912n of modulation frequency f_{mod} waveform 912, impedance tuner 762 may be configured to generate an impedance tuning over portions 912pn, 912np to attenuate peaks in reverse voltage Vsᵣₑᵥ waveform 916 for respective slopes m₁, m₃ resulting from slew rates in respective transitions 918pn, 918np. Further, in some configurations, impedance tuner 762 may provide improved impedance tuning by controlling the modulation frequency f_{mod} waveform 912 over portions 912n, 912p to vary slopes m₂, m₄.

In various configurations, a frequency setpoint or frequency offset for each half cycle can be determined using feedback control to servo tune source generator 712a to correct distortion, which varies in accordance with power delivered to the load, such as loads 532, 732. In various other configurations, a frequency setpoint or frequency offset for each half cycle can be determined by introducing perturbation signals into the output of source generator 712a and employing an extremum seeking control approach to adjusting the frequency of source generator 712a to minimize or maximize a parameter or cost varying in response to the perturbation. In various other configurations, the frequency setpoint or frequency offset for each half cycle can be determined by comparing a ratio of reflected or reverse power, voltage, or current to forward voltage, power, or current for a first frequency to a second frequency and adjusting to a frequency setpoint or frequency offset resulting in a lower ratio. In various other configurations, a frequency setpoint or frequency offset for each half cycle can be determined by storing a frequency setpoint or frequency offset, monitoring the change of impedance at the frequency setpoint or frequency offset, and updating the frequency setpoint or frequency offset if the impedance match is improved. The various frequency tuning methods described above are described in one or more of U.S. Pat. No. 8,576,013, issued Nov. 5, 2013, entitled Power Distortion-Based Servo Control Systems for Frequency Tuning RF Power Sources; U.S. Pat. No. 10,741,363, issued August 11, 2020, entitled Extremum Seeking Control Apparatus and Method for Automatic Frequency Tuning for RF Impedance Matching; U.S. Pat. No. 6,020,794, issued Feb. 1, 2000, entitled Ratiometric Autotuning Algorithm for RF Plasma Generator; and U.S. Pat. No. 9,947,514, issued Apr. 17, 2018, entitled Plasma RF Bias Cancellation System, all assigned to the assignee of the present application, and incorporated by reference herein.

With reference to FIG. 10, FIG. 10 shows waveforms 1010 indicating operation of one various configuration of the present disclosure. Waveforms 1010 include modulation frequency f_{mod} waveform 1012, source generator 712a forward voltage Vs_{fwd} waveform 1014, source generator 712a reverse voltage Vsᵣₑᵥ waveform 1016, bias generator 712a bias voltage V_{bias} waveform 1018, and sheath voltage Vₛₕₑₐₜₕ waveform 1020. Waveforms 1010 depict parameters similar to those of similarly referenced waveforms 910 of FIG. 9 and operate similarly. Various integrated circuit and device fabrication applications utilize increased or longer negative half cycle durations of pulsed DC voltage than the positive half cycle to apply a maximum flux of high energy ions. In such applications, impedance tuner 762 of source generator 712a may be configured to operate to provide impedance tuning, such as frequency tuning or reactive element adjustments, during the negative half cycle. As shown in FIG. 10, modulation frequency f_{mod} waveform 1012 shows only a single value corresponding to a constant source frequency tuning value for negative half cycle 1018n. During positive half cycle 1018p, impedance tuner 762 maintains the frequency set during negative half cycle 1018n. Referring to the non-limiting example values discussed in connection with FIG. 9, modulation frequency f_{mod} is set at 60.5 MHz during negative half cycle 1018n and maintained at 60.5 MHz during positive half cycle 1018p.

With reference to the effect of tuning during only negative half cycle 1018n, reverse voltage Vsᵣₑᵥ waveform 1016 indicates a reduced reverse voltage Vsᵣₑᵥ during 1016n, corresponding to impedance tuning during negative half cycle 1018n. Reverse voltage Vsᵣₑᵥ waveform 1016 indicates an increased reverse voltage Vsᵣₑᵥ 1016p corresponding to maintaining the negative half cycle 1018n frequency tuning value of modulation frequency f_{mod} waveform 1012 during the positive half cycle 1018p. Accordingly, during positive half cycle 1018p, source generator 712a will see higher reflected power during the positive half cycle 1018p. Higher reverse voltage 1016p will limit power delivered to load 732 during positive half cycle 1018p. In various applications, the higher reflected power may be acceptable if the positive duration is relatively short, as will be described below. In various other configurations, impedance tuner 762 may also optimize impedance tuning during positive half cycle 1018p.

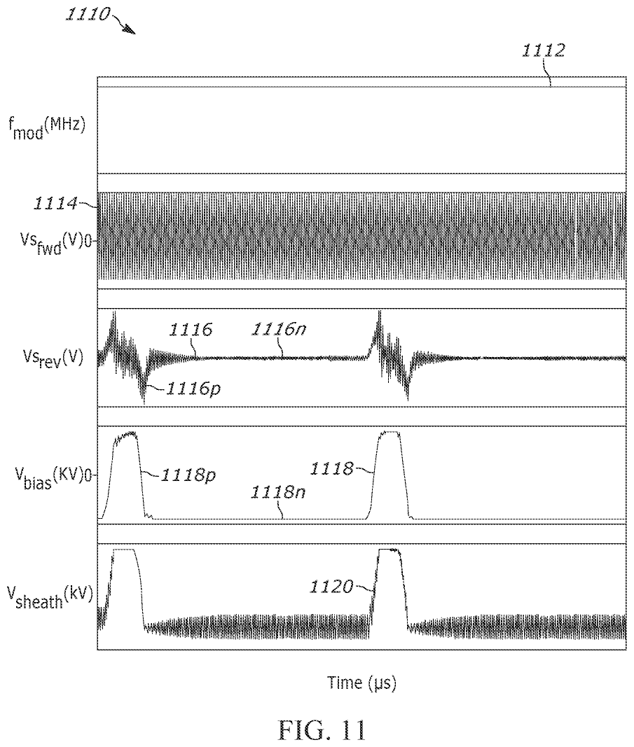

With reference to FIG. 11, FIG. 11 shows waveforms 1110 indicating operation of one various configuration of the present disclosure. Waveforms 1110 include modulation frequency f_{mod} waveform 1112, source generator 712a forward voltage Vs_{fwd} waveform 1114, source generator 712a reverse voltage Vsᵣₑᵥ waveform 1116, bias generator 712b bias voltage V_{bias} waveform 1118, and sheath voltage Vₛₕₑₐₜₕ waveform 1120. Waveforms 1110 depict parameters similar to those of similarly referenced waveforms 910 of FIG. 9 and 1010 of FIG. 10 and operate similarly. As referenced above with respect FIG. 10, waveforms 1110 describe operation of a system in which negative half cycle 1118n has a relatively long duration compared to positive half cycle 1118p. Similarly, as described in FIG. 10, modulation frequency f_{mod} waveform 1112 shows only a single value corresponding to a constant source frequency tuning value for negative half cycle 1118n. In the various configurations of FIG. 11, first generator 712a may operate at a fixed frequency. If source generator 712a operates at a fixed frequency, matching network 718 may include a variable impedance matching network 718 to minimize voltage, current, or power reflection during negative half cycle 1118n. In such a configuration, matching network 718 or a controller of FIG. 1 or 7 masks or blanks the output of a source voltage sensor, such as sensor 516a, during positive half cycle 1118p. Masking or blanking during positive half cycle 1118p allows impedance matching by matching network 718 only during negative half cycle 1118n. As shown in FIG. 11, reverse voltage Vsᵣₑᵥ waveform 1116 includes an extended, lower reverse power 1116n during negative half cycle 1118n and a shorter, higher reverse power 1116p during positive half cycle 1118p.

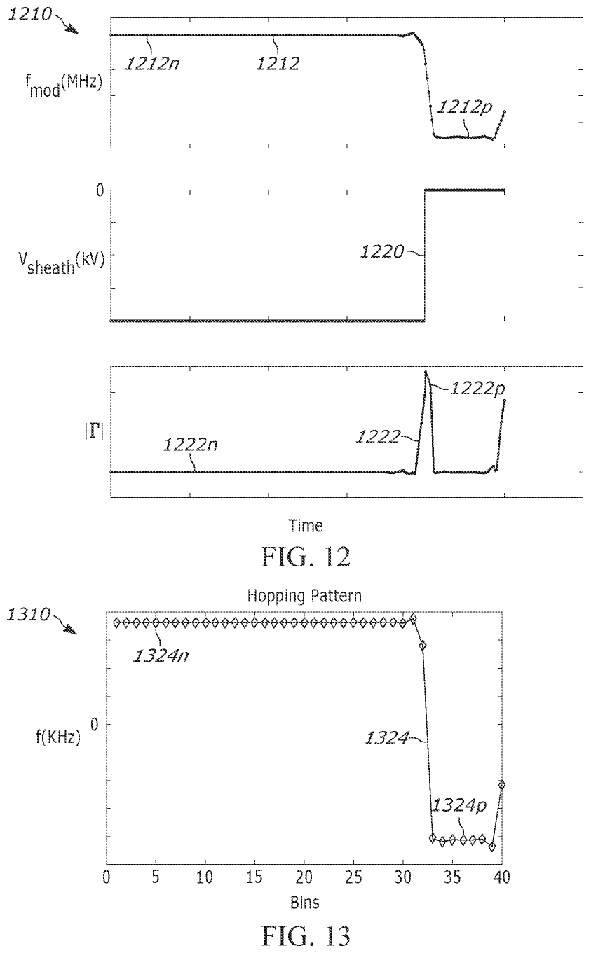

With reference to FIG. 12, FIG. 12 shows waveforms 1210 indicating operation of one various configuration of the present disclosure. Waveforms 1210 include modulation frequency f_{mod} waveform 1212, sheath voltage Vₛₕₑₐₜₕ waveform 1220, and gamma magnitude or Gmag (|Γ|) 1222. Waveforms 1210 depict selected parameters similar to those of similarly referenced waveforms of FIGS. 9-11, and such waveforms are similarly labeled as corresponding waveforms of FIGS. 9-11. FIG. 12 also includes sensed or measured parameter gamma magnitude or Gmag (|Γ|) 1222 (the absolute value of gamma (Γ)). FIG. 12 indicates operation of a RF generator system, such as power delivery system 710, in which impedance tuner 762 implements feedforward tuning of a frequency offset or hopping pattern to vary impedance. In systems in which frequency tuning includes frequency hopping capability, arbitrary bias envelopes can be tuned with the source frequency. In waveforms 1210 of FIG. 12, modulation frequency f_{mod} waveform 1212 and sheath voltage Vₛₕₑₐₜₕ waveform 1220 are as described above. Gmag (|Γ|) 1222 is a parameter that indicates the quality of the impedance match, with |Γ|=0 indicating an ideal match and |Γ|=1 indicating the most undesirable match.

By way of non-limiting example, modulation frequency f_{mod} is set at a first frequency 1212n over a negative half cycle of bias generator 712b (not shown in FIG. 12), and modulation frequency f_{mod} is set at a second frequency 1212p over a negative half cycle of bias generator 712b (not shown in FIG. 12). Gmag (|Γ|) waveform 1222 varies in accordance with the impedance match between source generator 712a and load 732. At 1212n of Gmag (|Γ|) waveform 1222, corresponding to a negative half cycle of bias generator 712b, the impedance match is better than at 1212p of Gmag (|Γ|) waveform 1222, corresponding to a positive half cycle of bias generator 712b. As shown in FIG. 12, Gmag (|Γ|) waveform 1222 includes an extended, lower Gmag (|Γ|) 1222n during negative half cycle (not shown in FIG. 12) and a shorter, higher Gmag (|Γ|) 1222p during positive half cycle 1118p (not shown in FIG. 12).

FIG. 13 indicates a hopping pattern 1310 over modulation frequency f_{mod} waveform 1324 for tuning the frequency of source generator 712a in accordance with modulation frequency f_{mod} waveform 1212. The hopping pattern includes a section 1324n corresponding to the negative half cycle of bias generator 712b and a section 1324p corresponding to the positive half cycle of bias generator 712b. In hopping pattern 1310 of FIG. 13, the frequency offset values remain generally constant at a first value over section 1324n and generally constant at a second value over section 1324p. In various configurations, the frequency offset at each negative half cycle or positive half cycle can also vary. Further, in various configurations, frequency hopping can be used to improve impedance matching in the transition region between section 1324n and section 1324p. In various configurations, frequency hopping can also be used to improve the impedance match across section 1324n and section 1324p using non-constant offsets across each region. The x-axis of FIG. 13 shows an index of bins of modulation frequency f_{mod} waveform 1324, and a frequency hopping pattern may be determined for each bin of modulation frequency f_{mod} waveform 1324. In the example of FIG. 13, 40 bins span a single pulse of modulation frequency f_{mod} waveform 1324, with approximately 30 bins spanning section 1324n, three bins spanning the transition between section 1324n and section 1324p, five bins spanning section 1324p, and two bins spanning the transition following section 1324p.

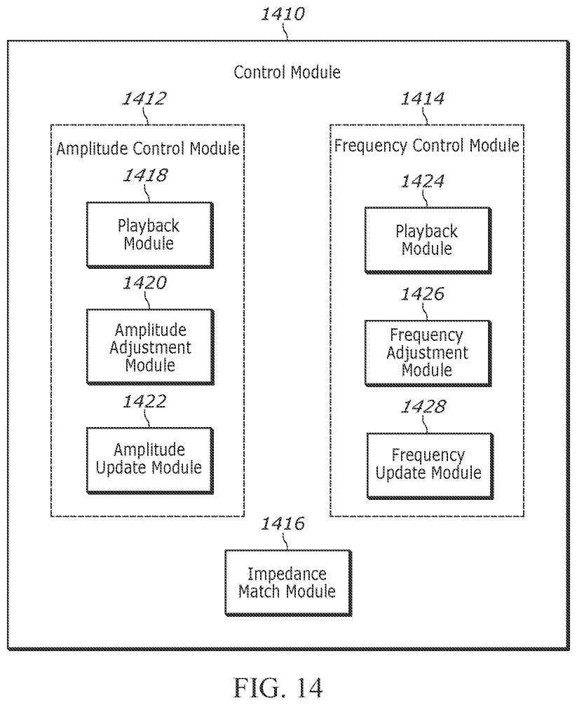

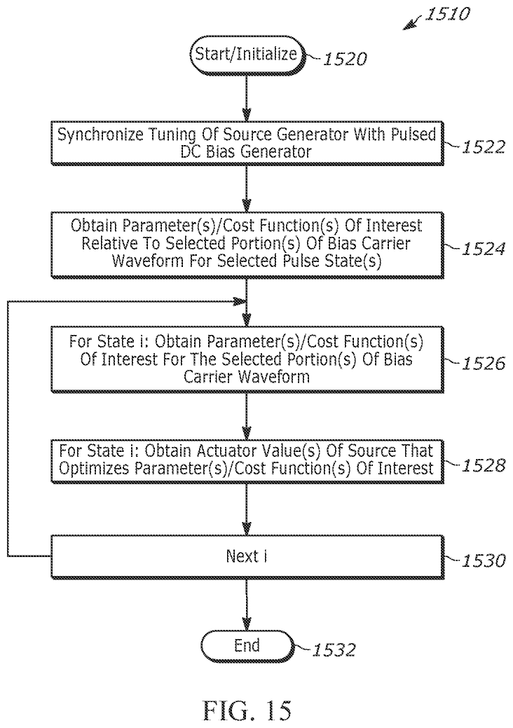

FIG. 14 incorporates various components of FIGS. 1 and 7. Control module 1410 may include amplitude control module section 1412, frequency control module section 1414, impedance match module section 1416. Amplitude control module section 1412 may include one or more of playback module 1418, amplitude adjustment module 1420, and amplitude update module 1422. Frequency control module section 1414 may include one or more of playback module 14 24, frequency adjustment module 1426, and frequency update module 1428. Impedance match module section 1416 may include a frequency control section or a reactive element control section. In various configurations, control module 1410 includes one or a plurality of processors that execute code associated with the module sections or modules 1410, 1412, 1414, 1416, 1418, 1420, 1422, 1424, 1426, and 1428. Operation of the module sections or modules, 1412, 1414, 1416, 1418, 1420, 1422, 1424, 1426, and 1428 is described below with respect to the method of FIG. 15.

In various configurations, one or more parameters of interest can be sensed, measured, or determined and individually or cooperatively form a basis for determining adjustments applied by impedance tuner 762. In various configurations, parameters of interest can include one or more of forward or reverse voltage, current, or power, gamma (Γ), Gmag (|Γ|), and mean standard deviation. In various other configurations, one or more of the above-reference parameters may be included in a cost function, either weighted or unweighted, and form a basis for determining adjustments applied by impedance tuner 762. In various configurations, the cost function may be maximized or minimized in order to determine adjustments applied by impedance tuner 762. Thus, impedance tuner 762 may determine or select impedance tuning values, such as frequency or reactive element values, in accordance with one or more of the above-referenced parameters or cost functions.

For further defined structure of controllers 520a, 520b, and 520′ of FIG. 5, also included in FIG. 7, see the below provided flow chart of FIG. 15 and the below provided definition for the term “module”. The systems disclosed herein may be operated using numerous methods, examples, and various control system methods of which are illustrated in FIGS. 5 and 7. Although the following operations are primarily described with respect to the implementations of FIGS. 5 and 7, the operations may be easily modified to apply to other implementations of the present disclosure. The operations may be iteratively performed. Although the following operations are shown and primarily described as being performed sequentially, one or more of the following operations may be performed while one or more of the other operations are being performed.

FIG. 15 shows a flow chart of a control system 1510 for performing mode-based impedance control for, for example, power delivery systems of FIGS. 5 and 7. Control begins at block 1520 and proceeds to block 1522. At block 1522, impedance tuning of source generator 712a is synchronized with pulsed DC output of bias generator 712b, as defined above. Control proceeds to block 1524 and parameter(s) or cost functions(s) of interest associated with the pulsed DC output of bias generator 712b are sensed, detected, measured, obtained, or determined for selected portions the bias carrier waveform of the pulsed DC signal output by bias generator 712b, such as the negative half cycle or positive half cycle, for one or more pulse states, such as S1, . . . , Sn of pulses P1, P2. Control proceeds to block 1526, and for state i of S1, . . . , Sn, parameter(s) or cost functions(s) of interest associated with the pulsed DC signal output by bias generator 712b are sensed, detected, measured, obtained, or determined for one or more portions of the pulsed DC signal output of bias generator 712b. Control proceeds to block 1528 and for state i, one or more actuator values are determined in accordance with optimizing the parameter(s) or cost functions(s) of interest. In various configurations, the one or more actuator values can be one or more of frequency of the output of source generator 712b or settings for variable reactive elements of matching network 718. Control proceeds to block 1530 in which i is incremented and control returns to block 1526. In various configurations, and as described above, not every state i may be processed at block 1526 and block 1528. In various configurations, selected states of S1, . . . , Sn of the bias waveform are not processed, similarly as described above with respect to FIGS. 10 and 11. Thus, in various configurations, less than all states of S1, . . . , Sn of the bias waveform are processed. Control terminates at block 1532.

The above described systems and methods may provide one or more of the following benefits. Reduced reflected power at source generator 512a, 712a results in lower operating temperatures of electronic components and reduced voltages and currents. Thus, source generator 512a, 712a experiences reduced stress. Because more power output by source generator 512a, 712a is delivered to the load, such as 532, 732, source generator 512a, 712a can be made smaller than conventional generators, thereby reducing costs. Further, reduced reflected power at source generator 512a, 712a improves accuracy of the sensor, such as sensor 516a of source generator 512a, providing improved power repeatability from load to load.

### CONCLUSION

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. In the written description and claims, one or more steps within a method may be executed in a different order (or concurrently) without altering the principles of the present disclosure. Similarly, one or more instructions stored in a non-transitory computer-readable medium may be executed in a different order (or concurrently) without altering the principles of the present disclosure. Unless indicated otherwise, numbering or other labeling of instructions or method steps is done for convenient reference, not to indicate a fixed order.

Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements.

The phrase “at least one of A, B, and C” should be construed to mean a logical (A OR B OR C), using a non-exclusive logical OR, and should not be construed to mean “at least one of A, at least one of B, and at least one of C.” The term “set” does not necessarily exclude the empty set—in other words, in some circumstances a “set” may have zero elements. The term “non-empty set” may be used to indicate exclusion of the empty set—in other words, a non-empty set will always have one or more elements. The term “subset” does not necessarily require a proper subset. In other words, a “subset” of a first set may be coextensive with (equal to) the first set. Further, the term “subset” does not necessarily exclude the empty set-in some circumstances a “subset” may have zero elements.

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” can be replaced with the term “controller” or the term “circuit.” In this application, the term “controller” can be replaced with the term “module.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); processor hardware (shared, dedicated, or group) that executes code; memory hardware (shared, dedicated, or group) that stores code executed by the processor hardware; other suitable hardware components that provide the described functionality; or a combination of some or all of the above, such as in a system-on-chip.

The module may include one or more interface circuits. In some examples, the interface circuit(s) may implement wired or wireless interfaces that connect to a local area network (LAN) or a wireless personal area network (WPAN). Examples of a LAN are Institute of Electrical and Electronics Engineers (IEEE) Standard 802.11-2020 (also known as the WIFI wireless networking standard) and IEEE Standard 802.3-2018 (also known as the ETHERNET wired networking standard). Examples of a WPAN are IEEE Standard 802.15.4 (including the ZIGBEE standard from the ZigBee Alliance) and, from the Bluetooth Special Interest Group (SIG), the BLUETOOTH wireless networking standard (including Core Specification versions 3.0, 4.0, 4.1, 4.2, 5.0, and 5.1 from the Bluetooth SIG).

The module may communicate with other modules using the interface circuit(s). Although the module may be depicted in the present disclosure as logically communicating directly with other modules, in various implementations the module may actually communicate via a communications system. The communications system includes physical and/or virtual networking equipment such as hubs, switches, routers, and gateways. In some implementations, the communications system connects to or traverses a wide area network (WAN) such as the Internet. For example, the communications system may include multiple LANs connected to each other over the Internet or point-to-point leased lines using technologies including Multiprotocol Label Switching (MPLS) and virtual private networks (VPNs).

In various implementations, the functionality of the module may be distributed among multiple modules that are connected via the communications system. For example, multiple modules may implement the same functionality distributed by a load balancing system. In a further example, the functionality of the module may be split between a server (also known as remote, or cloud) module and a client (or, user) module. For example, the client module may include a native or web application executing on a client device and in network communication with the server module.

Some or all hardware features of a module may be defined using a language for hardware description, such as IEEE Standard 1364-2005 (commonly called “Verilog”) and IEEE Standard 1076-2008 (commonly called “VHDL”). The hardware description language may be used to manufacture and/or program a hardware circuit. In some implementations, some or all features of a module may be defined by a language, such as IEEE 1666-2005 (commonly called “SystemC”), that encompasses both code, as described below, and hardware description.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

The memory hardware may also store data together with or separate from the code. Shared memory hardware encompasses a single memory device that stores some or all code from multiple modules. One example of shared memory hardware may be level 1 cache on or near a microprocessor die, which may store code from multiple modules. Another example of shared memory hardware may be persistent storage, such as a solid state drive (SSD), which may store code from multiple modules. Group memory hardware encompasses a memory device that, in combination with other memory devices, stores some or all code from one or more modules. One example of group memory hardware is a storage area network (SAN), which may store code of a particular module across multiple physical devices. Another example of group memory hardware is random access memory of each of a set of servers that, in combination, store code of a particular module.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of a non-transitory computer-readable medium are nonvolatile memory devices (such as a flash memory device, an erasable programmable read-only memory device, or a mask read-only memory device), volatile memory devices (such as a static random access memory device or a dynamic random access memory device), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. Such apparatuses and methods may be described as computerized apparatuses and computerized methods. The functional blocks and flowchart elements described above serve as software specifications, which can be translated into the computer programs by the routine work of a skilled technician or programmer.

The computer programs include processor-executable instructions that are stored on at least one non-transitory computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C #, Objective-C, Swift, Haskell, Go, SQL, R, Lisp, Java®, Fortran, Perl, Pascal, Curl, OCaml, JavaScript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A RF generator comprising:
a power source that outputs a time-varying signal to a load; and
at least one controller coupled to the power source, the at least one controller configured to generate an impedance control signal to control an impedance between the power source and the load, the at least one controller further configured to generate the impedance control signal in response to a pulsed DC output signal from a second power source.

2. The RF generator of claim 1, wherein pulsed DC output signal has a plurality of half cycles, and the impedance control signal varies in accordance with at least one of the plurality of half cycles.

3. The RF generator of claim 1, wherein the impedance control signal varies at least one of a frequency of the time-varying signal or an actuator command to a matching network.

4. The RF generator of claim 3, wherein the actuator command varies elements of a matching network, including at least one reactive element.

5. The RF generator of claim 1, wherein the pulsed DC output signal includes a plurality of half cycles, including a negative half cycle and a positive half cycle, and wherein the impedance control signal controls the impedance over the negative half cycle.

6. The RF generator of claim 5, wherein the negative half cycle has a duration longer than the positive half cycle.

7. The RF generator of claim 1, wherein pulsed DC output signal includes a plurality of half cycles, including a negative half cycle and a positive half cycle, and wherein the impedance control signal commands a first frequency of the time-varying signal during at least a portion of the negative half cycle.

8. The RF generator of claim 7, wherein the impedance control signal commands a second frequency of the time-varying signal during at least a portion of the positive half cycle.

9. The RF generator of claim 7, wherein the negative half cycle has a duration longer than the positive half cycle.

10. The RF generator of claim 1, wherein the pulsed DC output signal is modulated by an envelope signal including a plurality of states, and wherein the at least one controller includes a first impedance tuner configured to determine the impedance control signal for a first of the plurality of states and the at least one controller includes a second impedance tuner configured to determine the impedance control signal for a second of the plurality of states.

11. The RF generator of claim 1 wherein the impedance control signal varies a frequency of the time-varying signal using frequency hopping over a plurality of bins over at least a portion of the pulsed DC output signal.

12. A controller for a power generator comprising:
an impedance tuner coupled to a power source that outputs a time-varying signal to a load, the impedance tuner configured to generate an impedance control signal to control an impedance match between the power source and the load, the impedance tuner further configured to generate the impedance control signal in response to a pulsed DC output signal from a second power source.

13. The controller of claim 12, wherein the pulsed DC output signal has a plurality of half cycles, and the impedance control signal varies in accordance with at least one of the plurality of half cycles.

14. The controller of claim 12, wherein the impedance control signal varies at least one of a frequency of the time-varying signal or an actuator command to a matching network.

15. The controller of claim 14, wherein the actuator command varies elements of a matching network, including at least one reactive element.

16. The controller of claim 12, wherein the pulsed DC output signal has a plurality of half cycles, including a negative half cycle and a positive half cycle, and wherein the impedance control signal controls the impedance match over the negative half cycle and does not control the impedance match over the positive half cycle.

17. The controller of claim 16, wherein the negative half cycle has a duration longer than the positive half cycle.

18. The controller of claim 12, wherein the pulsed DC output signal has a plurality of half cycles, including a negative half cycle and a positive half cycle, and wherein the impedance control signal commands a first frequency of the time-varying signal during at least a portion of the negative half cycle.

19. The controller of claim 18, wherein the impedance control signal commands a second frequency of the time-varying signal during at least a portion of the positive half cycle.

20. The controller of claim 18, wherein the negative half cycle has a duration longer than the positive half cycle.

21. The controller of claim 12, wherein the pulsed DC output signal has a plurality of half cycles, and wherein the impedance tuner includes a first tuner configured to determine the impedance control signal for a first of the plurality of half cycles and the impedance tuner includes a second tuner configured to determine the impedance control signal for a second of the plurality of half cycles.

22. The controller of claim 12 wherein the impedance control signal varies a frequency of the time-varying signal using frequency hopping over a plurality of bins over at least a portion of the pulsed DC output signal.

23. A non-transitory computer-readable medium storing instructions, the instructions comprising:
controlling an impedance tuner coupled to a power source that outputs a RF signal to a load;
generating an impedance control signal to control an impedance match between the power source and the load; and
generating the impedance control signal in response to a pulsed DC output signal from a second power source.

24. The non-transitory computer-readable medium storing instructions of claim 23, wherein the pulsed DC output signal has a plurality of half cycles, the instructions comprising:
varying the impedance control signal in accordance with at least one of the plurality of half cycles.

25. The non-transitory computer-readable medium of claim 23, the instructions comprising:
varying at least one of a frequency of the RF signal or an actuator command to a matching network,
wherein varying elements of a matching network, including at least one reactive element.

26. The non-transitory computer-readable medium of claim 23, wherein the pulsed DC output signal has a plurality of half cycles, including a negative half cycle and a positive half cycle, the instructions comprising:
controlling an impedance over the negative half cycle and not controlling the impedance in over the positive half cycle.

27. The non-transitory computer-readable medium of claim 23, wherein the pulsed DC output signal has a plurality of half cycles, including a negative half cycle and a positive half cycle, the instructions comprising:
controlling a first frequency of the RF signal during at least a portion of the negative half cycle.

28. The non-transitory computer-readable medium of claim 27, the instructions comprising:
controlling a second frequency of the RF signal during at least a portion of the positive half cycle.

29. The non-transitory computer-readable medium of claim 23, wherein the pulsed DC output signal has a plurality of half cycles, the instructions comprising:
determining the impedance control signal for a first of the plurality of half cycles; and
determining the impedance control signal for a second of the plurality of half cycles.
